(19) United States
(12) Patent Application Publication
(10) Pub. No.: US 2025/0273477 A1
(43) Pub. Date: Aug. 28, 2025

(54) SEMICONDUCTOR PROCESSING FOR FORMING ISOLATION STRUCTURE IN SEMICONDUCTOR SUBSTRATE

(71) Applicant: TEXAS INSTRUMENTS INCORPORATED, Dallas, TX (US)

(72) Inventors: Mahalingam Nandakumar, Richardson, TX (US); Jonathan Brown, Lehi, UT (US); Matthew Willford, Lehi, UT (US); SK Saiful Islam, Lehi, UT (US); Andrew Merrell, Lehi, UT (US); Gordon Nielsen, Cedar Hills, UT (US); Brian Ellingwood, Millcreek, UT (US); Haowen Bu, Wylie, TX (US); Byron Palla, Murphy, TX (US); Douglas Newman, Crowley, TX (US)

(21) Appl. No.: 18/585,539

(22) Filed: Feb. 23, 2024

(51) Int. Cl. H01L 21/473; H01L 21/02; H01L 21/465; H01L 21/477

(52) U.S. Cl. CPC H01L 21/473; H01L 21/02063; H01L 21/02164; H01L 21/0217; H01L 21/02271; H01L 21/465; H01L 21/477

(57) ABSTRACT

The present disclosure generally relates to semiconductor processing for forming an isolation structure in a semiconductor substrate. In an example, a first dielectric layer is formed over a semiconductor substrate. A second dielectric layer is formed over the first dielectric layer. A recess is formed through the second dielectric layer and the first dielectric layer into the semiconductor substrate. The recess is cleaned. Cleaning the recess includes using an etchant. A ratio of an etch rate of the first dielectric layer by the etchant to an etch rate of the second dielectric layer by the etchant is in a range from 0.10 to 4. The recess in the semiconductor substrate is filled with a dielectric material.

### BACKGROUND

In integrated circuits (ICs), various semiconductor devices have components formed in a semiconductor substrate. For proper functioning of the IC, the devices may need to have some components electrically isolated from other components. Various isolation technologies have been implemented to electrically isolate components of a device that are in a semiconductor substrate from other components of other devices that are also in the semiconductor substrate.

### SUMMARY

An example is a method. A first dielectric layer is formed over a semiconductor substrate. A second dielectric layer is formed over the first dielectric layer. A recess is formed through the second dielectric layer and the first dielectric layer into the semiconductor substrate. The recess is cleaned. Cleaning the recess includes using an etchant. A ratio of an etch rate of the first dielectric layer by the etchant to an etch rate of the second dielectric layer by the etchant is in a range from 0.10 to 4. The recess in the semiconductor substrate is filled with a dielectric material.

Another example is a method. An oxide layer is formed over a semiconductor substrate. A nitride layer is formed over the oxide layer. The nitride layer has an etch rate by hydrofluoric acid in a range from 20 Angstroms per minute (Å/m) to 30 Å/m. A trench is formed through the nitride layer and the oxide layer into the semiconductor substrate. The trench is cleaned. Cleaning the trench includes using hydrofluoric acid. The trench in the semiconductor substrate is filled with a dielectric material.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a flow chart of a method for manufacturing a semiconductor device according to some examples.

FIGS. 2, 3, 4, 5, 6, 7, 8, 9, 10, 11A, 11B, 12, 13, 14, and 15 are respective cross-sectional views of a semiconductor device in intermediate stages of manufacturing according to some examples.

FIG. 16 is a flowchart of a method for depositing a mask dielectric layer according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for forming an isolation structure in a semiconductor substrate. In some examples, a first dielectric layer is formed over a semiconductor substrate, and a second dielectric layer is formed over the first dielectric layer. A recess is formed through the second and first dielectric layers into the semiconductor substrate. A cleaning is performed to clean the recess. The cleaning includes using an etchant. A ratio of an etch rate of the first dielectric layer by the etchant to an etch rate of the second dielectric layer by the etchant may be in a range from 0.10 to 4. The recess is filled with a dielectric material. Some examples may obviate using an additional etchant, such as phosphoric (H₃PO₄) acid, that may damage a surface of the semiconductor substrate and/or that may result in contamination in the formed isolation structure in the semiconductor substrate. Additionally, some examples may permit engineering a divot at respective corners of the isolation structure and semiconductor substrate that may achieve a target active area utilization while reducing a parasitic sub-threshold transistor effect. Other benefits and advantages may be achieved.

Various examples are described subsequently. Although the specific examples may illustrate various aspects of the above generally described features, examples may incorporate any combination of the above generally described features (which are described in more detail in examples below).

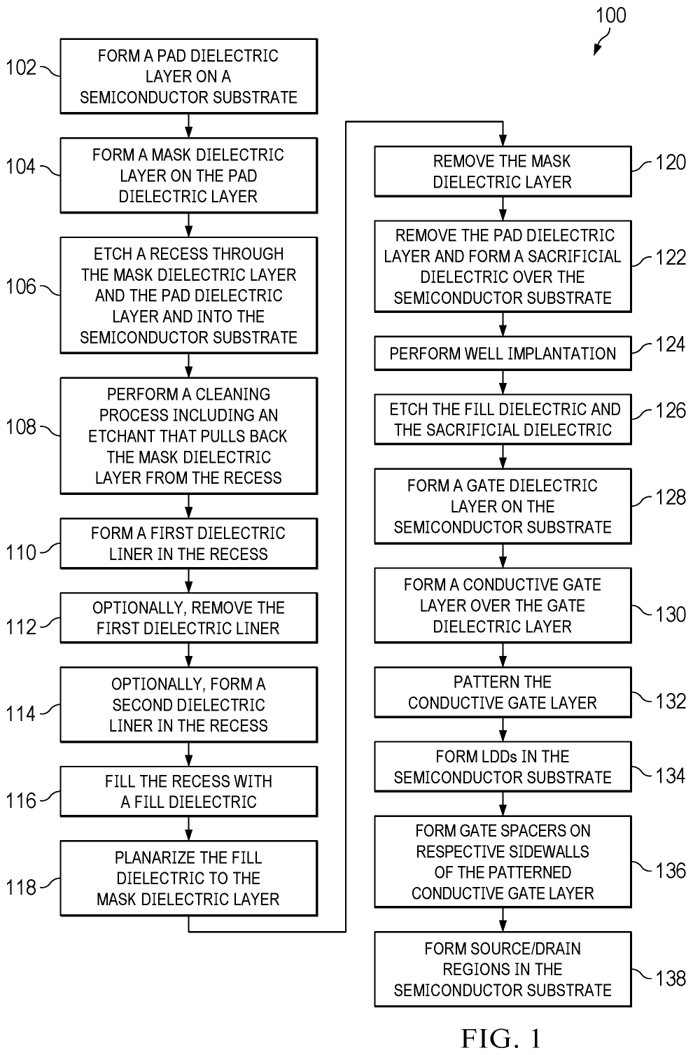

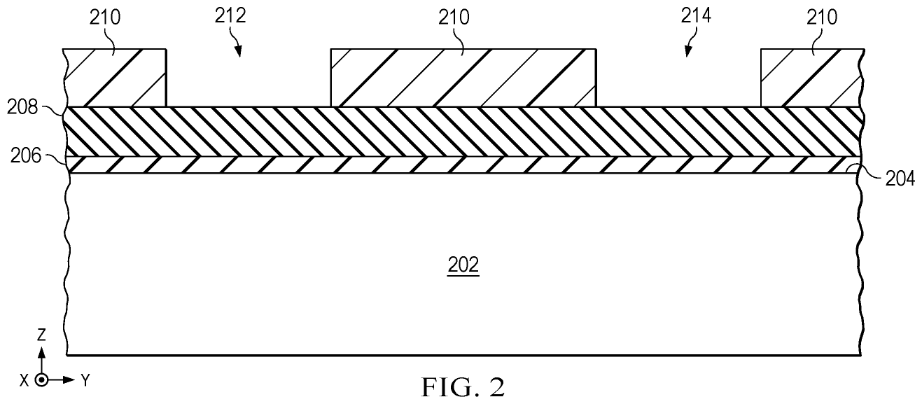

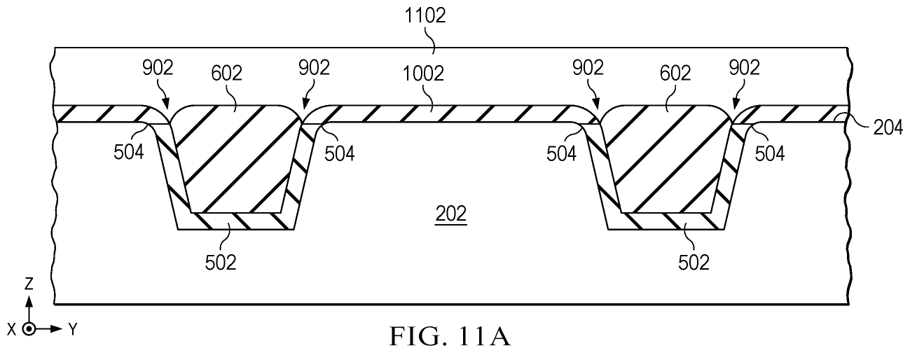

FIG. 1 is a flow chart of a method 100 for manufacturing a semiconductor device according to some examples. FIGS. 2 through 10, 11A, 11B, and 12 through 15 are respective cross-sectional views of a semiconductor device in intermediate stages of manufacturing according to some examples. FIGS. 2 through 10 and 11A are respective cross-sectional views in a Y-Z plane, and FIGS. 11B and 12 through 15 are respective cross-sectional views in an X-Z plane perpendicular to the Y-Z plane. The method 100 of FIG. 1 is described herein in the context of FIGS. 2 through 15.

Referring to block 102 of FIG. 1 and to FIG. 2, a pad dielectric layer 206 is formed on a semiconductor substrate 202. The semiconductor substrate 202 may be or include a bulk semiconductor substrate, a semiconductor-on-insulator (SOI) substrate, or any other appropriate substrate. The semiconductor substrate 202 may also include a support (or handle) substrate and an epitaxial layer epitaxially grown on the support substrate. In some examples, the semiconductor substrate 202 is or includes a silicon substrate (which may be singulated from a bulk silicon wafer at the conclusion of semiconductor processing). In further examples, the semiconductor substrate 202 includes a silicon substrate with an epitaxial silicon layer grown thereon. The semiconductor substrate 202 is or includes a semiconductor material in and/or on which devices, such as field effect transistors (FETs) and/or diodes (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 202 has an upper surface 204 in and/or on which devices (e.g., FETs as described subsequently) are formed. In the illustrated example, the semiconductor material of the semiconductor substrate 202 is doped, such as p-type doped with a p-type dopant. Another dopant type may be implemented.

The pad dielectric layer 206 is formed on the upper surface 204 of the semiconductor substrate 202. In some examples, the pad dielectric layer 206 is an oxide (e.g., a pad oxide layer), such as silicon oxide. The pad dielectric layer 206 may be formed by oxidizing the semiconductor material of the semiconductor substrate 202 at the upper surface 204. The oxidation process may be or include a thermal oxidation, in situ steam generation (ISSG) oxidation, or the like. In examples in which the semiconductor material of the semiconductor substrate 202 at the upper surface 204 is silicon, the pad dielectric layer 206 may be silicon oxide. In other examples, the pad dielectric layer 206 may be formed by another process, such as a deposition, like chemical vapor deposition (CVD) or the like. In some examples, the pad dielectric layer 206 may have a thickness in a range from 50 Å to 200 Å, such as from 108 Å to 112 Å.

Referring to block 104 of FIG. 1 and to FIG. 2, a mask dielectric layer 208 is formed on the pad dielectric layer 206. The mask dielectric layer 208 is or includes a material different from the pad dielectric layer 206. The mask dielectric layer 208 may be selectively etched relative to the pad dielectric layer 206, and vice versa. In some examples, a ratio of an etch rate of the pad dielectric layer 206 by an etchant (e.g., diluted hydrofluoric (dHF) acid) of a subsequent cleaning process (e.g., in block 108 described subsequently) to an etch rate of the mask dielectric layer 208 by the etchant is in a range from about 0.10 to about 4. In some examples, the etch rate of the mask dielectric layer 208 by the etchant of the subsequent cleaning process is in a range from 3 Angstroms per minute (Å/minute) to 100 Å/minute, such as in a range from 20 Å/minute to 30 Å/minute, and the etch rate of the pad dielectric layer 206 by the etchant of the subsequent cleaning process is in a range from 27 Å/minute to 29 Å/minute. In some examples, the mask dielectric layer 208 is or includes a nitride, such as silicon nitride. More specifically, in some examples, the mask dielectric layer 208 is silicon nitride having an etch rate in a range from 20 Å/minute to 30 Å/minute in diluted hydrofluoric (dHF) acid that is 100:1 H₂O:HF. In some examples, the mask dielectric layer 208 may have a thickness in a range from 880 Å to 920 Å. The mask dielectric layer 208 may be formed by various processes or techniques, such as described below.

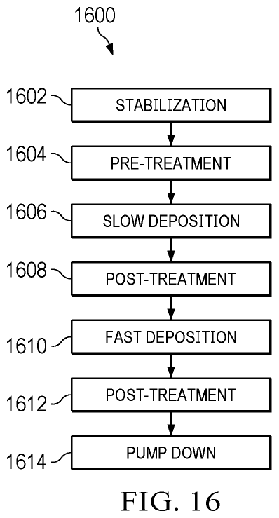

In some examples, the mask dielectric layer 208 may be deposited by implementing multiple sub-processes. FIG. 16 is a flowchart of a method 1600 for depositing the mask dielectric layer 208 according to some examples. The mask dielectric layer 208 is or includes a nitride, such as silicon nitride, in these examples. In some examples, such as described, the method 1600 is performed in a chamber of a processing tool—e.g., each sub-process of the method 1600 is performed in the same chamber (e.g., in situ). Further, each sub-process of the method 1600 may be performed in the chamber while maintaining a pressure of the chamber at a sub-atmospheric level.

At block 1602, a first sub-process includes stabilization of the ambient in and/or components of the chamber. Inert gas flow(s), pressure, temperature, and heater spacing are brought to a stable state in the first sub-process before beginning deposition of the mask dielectric layer 208. During the stabilization, precursor gases, such as silicon-containing precursor gas (e.g., silane (SiH₄)) and a nitrogen-containing precursor gas (e.g., ammonia (NH₃)), are not flowed into the chamber. Further, during the stabilization, a radio frequency (RF) power is not supplied to a plasma inducing component (e.g., an electrode or coil), such that no plasma is created in the chamber during the stabilization. In some examples, the processing tool is configured to generate a capacitively coupled plasma (CCP), and hence, the plasma inducing component may be an electrode used to generate a plasma. In other examples, the processing tool may be configured to generate an inductively coupled plasma (ICP), and hence, the plasma inducing component may be a coil used to generate a plasma.

At block 1604, a second sub-process includes a pre-treatment. The second sub-process may be for interface management and may remove substrate moisture and volatile material. In some examples, helium (He) gas and nitrogen (N₂) gas are flowed into the chamber, which may make the underlying layer (e.g., the pad dielectric layer 206) moisture free, may remove volatile materials from the underlying layer, and may make the underlying layer bonded with nitrogen that was broken down from the nitrogen (N₂) gas. The pre-treatment may permit a subsequently deposited nitride layer to have very good adhesion to the underlying layer and may permit the interface therebetween to be quite smooth.

In some examples, the pre-treatment process includes flowing a mixture of gases, including helium (He) gas and nitrogen (N₂) gas in the absence of a precursor gas(es) (e.g., a silicon-containing precursor gas (e.g., silane (SiH₄)) and a nitrogen-containing precursor gas (e.g., ammonia (NH₃)). A flow rate of the helium (He) gas is in a range from 8,000 standard cubic centimeter (sccm) to 12,000 sccm, and a flow rate of the nitrogen (N₂) gas is in a range from 8,000 sccm to 12,000 sccm. The pre-treatment process includes a chamber pressure in a range from 6 torr to 10 torr. The pre-treatment process includes a process temperature (e.g., a temperature of a pedestal that supports the semiconductor substrate, a temperature of an ambient environment within a chamber, etc.) in a range from 400° C. to 575° C. An RF power in a range from 150 Watts (W) to 300 W may be supplied to a plasma inducing component (e.g., an electrode or coil), such that plasma is created in the chamber during the pre-treatment process.

At block 1606, a third sub-process includes a slow deposition. In some examples, the third sub-process deposits a nitride layer to a thickness up 25 Å. A slow deposition rate may be achieved by a very low flow rate of a silicon-containing precursor gas, such as silane (SiH₄), a much higher flow rate of a nitrogen-containing precursor gas, such as ammonia (NH₃), together with a very high flow rate of nitrogen (N₂) gas and another inert gas, such as helium (He). In some examples, a ratio of the flow rate of the nitrogen-containing precursor gas to the flow rate of the silicon-containing precursor gas may be greater than 4.28, such as in a range from 4.28 to 27. In some examples, a ratio of the flow rate of the nitrogen (N₂) gas to the flow rate of the silicon-containing precursor gas may be greater than 200, such as in a range from 200 to 1,000, and a ratio of the flow rate of the other inert gas to the flow rate of the silicon-containing precursor gas to may be greater than 285, such as in a range from 285 to 1,334. In some examples, a ratio of the flow rate of the nitrogen (N₂) gas to the flow rate of the nitrogen-containing precursor gas may be greater than 46, such as in a range from 46 to 100, and a ratio of the flow rate of the other inert gas to the flow rate of the nitrogen-containing precursor gas may be greater than 1.42, such as in a range from 1.42 to 37.5.

In some examples, the slow deposition process is a high temperature CVD (HT-CVD), which may further be a plasma enhanced CVD (PECVD). The slow deposition process includes a gas mixture that includes a silicon-containing precursor gas (e.g., silane (SiH₄)), a nitrogen-containing precursor gas (e.g., ammonia (NH₃)), nitrogen (N₂) gas, and another inert gas (e.g., helium (He) or argon (Ar)). In some examples, a flow rate of the silicon-containing precursor gas is in a range from 15 sccm to 35 sccm, and a flow rate of the nitrogen-containing precursor gas is in a range from 150 sccm to 400 sccm. In some examples, a flow rate of nitrogen (N2) gas is in a range from 7,000 sccm to 15,000 sccm, and a flow rate of helium (He) gas is in a range from 10,000 sccm to 20,000 sccm. The slow deposition process may include a chamber pressure in a range from 6 torr to 10 torr. In some examples, the slow deposition process may include a process temperature in a range from 400° C. to 575° C. The slow deposition process may include an RF power in the range from 200 W to 400 W. The slow deposition process may slowly deposit nitride on the pad dielectric layer 206, so that good adhesion between the pad dielectric layer 206 and the mask dielectric layer 208 may be achieved.

At block 1608, a fourth sub-process includes a post-treatment. The fourth sub-process may densify the deposited nitride layer and make the nitride layer like a more stoichiometric composition. The post-treatment may flow nitrogen (N₂) gas and helium (He) gas with a high RF power. During the post-treatment, a precursor gas(es), such as a silicon-containing precursor gas (e.g., silane (SiH₄)) and a nitrogen-containing precursor gas (e.g., ammonia (NH₃)), are not flowed into the chamber. The post-treatment may reduce Si—H bonds by removing hydrogen from silicon (Si) and may replace dangling Si bonds with more nitrogen, which increases layer quality and purity. This may make the layer more robust.

In some examples, the post-treatment process includes flowing a mixture of gases, including helium (He) gas and nitrogen (N₂) gas in the absence of a precursor gas(es) (e.g., a silicon-containing precursor gas (e.g., silane (SiH₄) and a nitrogen-containing precursor gas (e.g., ammonia (NH₃)). A flow rate of the helium (He) gas is in a range from 8,000 sccm to 12,000 sccm, and a flow rate of the nitrogen (N₂) gas is in a range from 12,000 sccm to 16,000 sccm. The post-treatment process includes a chamber pressure in a range from 4 torr to 6 torr. The post-treatment process includes a process temperature in a range from 400° C. to 575° C. The post-treatment process includes an RF power in the range from 200 W to 300 W.

At block 1610, a fifth sub-process includes a fast deposition. The fast deposition may deposit a remainder of the mask dielectric layer 208. The fast deposition deposits nitride at a rate greater than the slow deposition, such as at a rate that is at least 3 Å/minute greater than the rate of the slow deposition. A high deposition rate may be achieved by high flow rates of a silicon-containing precursor gas, such as silane (SiH₄), and a nitrogen-containing precursor gas, such as ammonia (NH₃), and lower RF power with respect to earlier slow deposition step. The fast deposition process may implement a flow rate of a silicon-containing precursor gas (e.g., silane (SiH₄)) that is greater than a flow rate of a silicon-containing precursor gas (e.g., silane (SiH₄)) of the slow deposition process. The fast deposition process may implement a flow rate of a nitrogen-containing precursor gas (e.g., ammonia (NH₃)) that is greater than a flow rate of a nitrogen-containing precursor gas (e.g., ammonia (NH₃)) of the slow deposition process. The fast deposition may implement a lower RF power than an RF power of the slow deposition. Quality of the mask dielectric layer 208 may be achieved by a ratio of respective flow rates of ammonia (NH₃) gas to silane (SiH₄) gas of 1.66 to 5.33, a higher process temperature, such as 550° C. or higher, a higher flow rate of inert gas, and a lower RF power than an RF power of the slow deposition.

In some examples, the fast deposition process is an HT-CVD, which may further be a PECVD. The fast deposition process includes a gas mixture that includes a silicon-containing precursor gas (e.g., silane (SiH₄)), a nitrogen-containing precursor gas (e.g., ammonia (NH₃))), nitrogen (N₂) gas, and another inert gas (e.g., helium (He) or argon (Ar)). In some examples, a flow rate of the silicon-containing precursor gas is in a range from 160 sccm to 300 sccm, and a flow rate of the nitrogen-containing precursor gas is in a range from 500 sccm to 800 sccm. In some examples, a flow rate of nitrogen (N₂) gas is in a range from 7,000 sccm to 15,000 sccm, and a flow rate of helium (He) gas is in a range from 5,000 sccm to 20,000 sccm. The fast deposition process may include a chamber pressure in a range from 2 torr to 4 torr. In some examples, the fast deposition process may include a process temperature in a range from 400° C. to 575° C. The fast deposition process may include an RF power in the range from 75 W to 150 W. Dilution of reactive precursor gases (e.g., silane (SiH₄) gas and ammonia (NH₃) gas) with inert gas (e.g., helium (He) gas) may reduce hydrogen in the mask dielectric layer 208 and form the mask dielectric layer 208 toward a stoichiometric composition.

At block 1612, a sixth sub-process includes a post-treatment. The sixth sub-process may be like the fourth sub-process of block 1608. At block 1614, a seventh sub-process includes a pump down of the chamber in preparation for transferring the semiconductor substrate 202 out of the chamber.

In some examples, the mask dielectric layer 208 may be deposited by implementing hexachlorodisilane (HCDS, Si₂Cl₆) gas as a silicon-containing precursor gas. The deposition process may be a CVD. In some examples, the deposition process includes flowing a mixture of gases, including a silicon-containing precursor gas (e.g., hexachlorodisilane (HCDS, Si₂Cl₆)), a nitrogen-containing precursor gas (e.g., ammonia (NH₃)), and a carrier (e.g., inert) gas (e.g., helium (He)). A flow rate of the silicon-containing precursor gas is in a range from 5 sccm to 100 sccm, and a flow rate of the nitrogen-containing precursor gas is in a range from 100 sccm to 3,000 sccm. A flow rate of the carrier gas is in a range up to 2,000 sccm (e.g., which may include implementing no carrier gas). The deposition process includes a chamber pressure in a range from 0.1 torr to 0.5 torr. In some examples, the deposition process includes a process temperature in a range from 450° C. to 650° C.

In some examples, the mask dielectric layer 208 is a silicon-rich nitride (SRN) layer. An SRN layer may have an atomic content of silicon greater than stoichiometric silicon nitride (Si₃N₄). An atomic ratio of silicon to nitride in stoichiometric silicon nitride (Si₃N₄) is 0.75 (e.g., 3:4), and an SRN layer may have an atomic ratio of silicon to nitride of greater than 0.75, such as greater than 0.9. In some examples, an SRN layer has an atomic ratio of silicon to nitride in a range from 0.9 to 1.1. An SRN layer may be formed using PECVD. A deposition process for forming an SRN layer may include flowing a silicon-containing precursor gas (e.g., silane (SiH₄)) and a nitrogen-containing precursor gas (e.g., ammonia (NH₃)). In some examples, to form an SRN layer, a ratio of the flow rate of the silicon-containing precursor gas to the flow rate of the nitrogen-containing precursor gas is greater than 1:20, such as 1:1.6. Using a ratio of 1:1.6 has been observed to achieve an atomic ratio of silicon to nitrogen of 3:2 in an SRN layer.

In some examples, a deposition process for forming an SRN may be a CVD, such as a PECVD. The deposition process includes flowing a mixture of gases, including a silicon-containing precursor gas (e.g., silane (SiH₄)), a nitrogen-containing precursor gas (e.g., ammonia (NH₃)), and a carrier (e.g., inert) gas (e.g., helium (He)). A flow rate of the silicon-containing precursor gas is in a range from 200 sccm to 350 sccm, and a flow rate of the nitrogen-containing precursor gas is in a range from 700 sccm to 1,000 sccm. A flow rate of the carrier gas is in a range from 5,000 sccm to 10,000 sccm. The deposition process includes a chamber pressure in a range from 4 torr to 8 torr. The deposition process includes a process temperature less than 375° C., such as 350° C. or less. The deposition process may include an RF power in the range from 150 W to 300 W. A deposition rate of an SRN layer by the deposition process may be about 20 Å/second.

Forming the mask dielectric layer 208 at block 104 may also include performing an anneal after depositing the mask dielectric layer 208. Generally, when the mask dielectric layer 208 is silicon nitride, it is believed that some deposition processes described herein may deposit the silicon nitride with a high hydrogen content that renders the silicon nitride less dense and more reactive with hydrofluoric (HF) acid. Hence, as deposited, the silicon nitride may have an etch rate in diluted hydrofluoric (dHF) acid that is relatively fast.

To tune the etch rate, in some examples, an anneal process may be implemented. The anneal process may densify the mask dielectric layer 208. The anneal process may cause hydrogen to outgas from the mask dielectric layer 208, which may result in a denser material of the mask dielectric layer 208 and may result in the mask dielectric layer 208 being less reactive with hydrofluoric (HF) acid. The anneal may cause the mask dielectric layer 208 to shrink (e.g., having a reduction in thickness or lateral width) Further, the anneal process may tune a stress of the mask dielectric layer 208. Densifying and/or stress tuning may contribute to obtaining a target etch rate of the mask dielectric layer 208. The anneal process may balance an anneal temperature and an anneal duration. For example, a longer anneal duration may permit an anneal temperature to be lower, and a higher anneal temperature may permit an anneal duration to be shorter. In some examples, the anneal process (e.g., for an in-situ or external furnace anneal) includes a temperature in a range from 650° C. to 850° C. for a duration up to 90 minutes. In some examples, the anneal process (e.g., for a rapid thermal process (RTP)) includes a temperature in a range from 900° C. to 1,000° C. for a duration of a spike anneal up to 90 seconds.

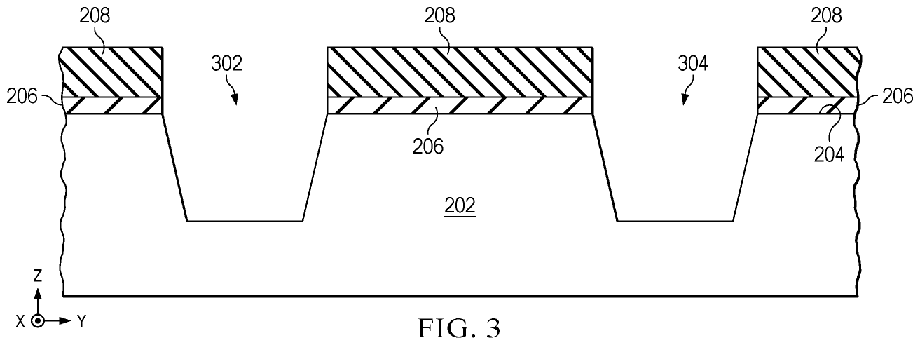

Referring to block 106 of FIG. 1 and to FIGS. 2 and 3, a recess 302, 304 is etched through the mask dielectric layer 208 and the pad dielectric layer 206 and into the semiconductor substrate 202. As shown in FIG. 3, recesses 302, 304 (e.g., trenches) are formed in the semiconductor substrate 202. As shown in FIG. 2, a photoresist 210 is deposited (e.g., by spin-on) over the mask dielectric layer 208 and patterned using photolithography to have openings 212, 214 exposing the mask dielectric layer 208 where the recesses 302, 304 are to be formed. Using the photoresist 210 as a mask, an etch process is performed to etch the mask dielectric layer 208, pad dielectric layer 206, and semiconductor substrate 202 through the openings 212, 214 to thereby form the recesses 302, 304. The etch process may be any anisotropic etch, such as a reactive ion etch (RIE). After the etch process, the photoresist 210 is removed, such as by ashing. As shown in FIG. 3, for a given recess 302, 304, corresponding sidewalls of the pad dielectric layer 206 and mask dielectric layer 208 are aligned.

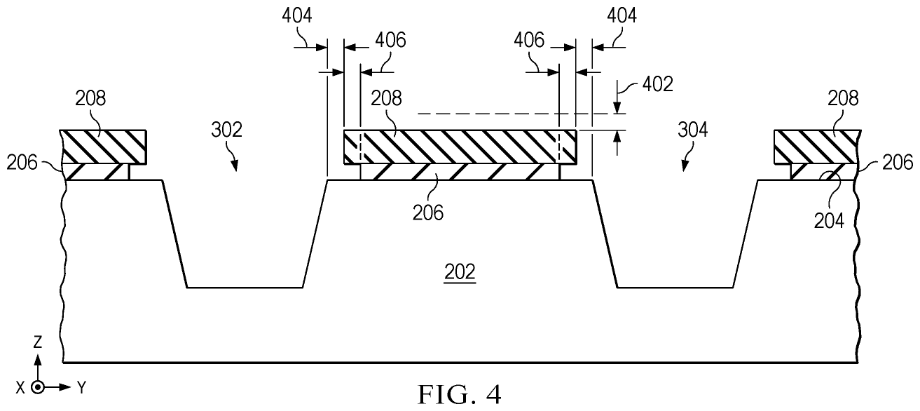

Referring to block 108 of FIG. 1 and to FIG. 4, a cleaning process that includes the etchant referenced previously is performed that pulls back the mask dielectric layer 208 from the recess 302, 304. The cleaning process also pulls back the pad dielectric layer 206 from the recess 302, 304 at a greater or lesser rate and/or amount than the mask dielectric layer 208. Hence, the cleaning process may undercut the mask dielectric layer 208 proximate the recess 302, 304. The pull back (in conjunction with the undercut in some cases) of the mask dielectric layer 208 may permit a portion of the upper surface 204 of the semiconductor substrate 202 at or near a corner of the respective recess 302, 304 to be exposed to, in some examples, an oxidation process for forming a dielectric liner, as described subsequently. Exposing this portion of the upper surface 204 for oxidation may permit the corner to be more protected during processing, which may permit improved divot control.

In some examples, the cleaning process includes a wet cleaning. More specifically, in some examples, the cleaning process includes using a diluted hydrofluoric (dHF) acid followed by a Standard Clean 1 (SC1) cleaning process, which is followed by a diluted hydrochloric (dHCl) acid. The diluted hydrofluoric (dHF) acid may have a ratio of 100 parts water (H₂O) to one part hydrofluoric (HF) acid (e.g., 100:1 H₂O:HF). The cleaning process (e.g., the dHF acid) isotropically etches the mask dielectric layer 208. Hence, a thickness of the mask dielectric layer 208 is reduced by an amount 402. Also, lateral dimensions of the mask dielectric layer 208 from sidewalls are reduced by an amount 404 (e.g., a lateral distance from a corresponding boundary of the respective trench 302, 304). For example, a thickness of the mask dielectric layer 208 may be reduced in a range from 50 Å to 200 Å, such as in a range from 60 Å to 70 Å, and a lateral dimension of the mask dielectric layer 208 may be reduced from a given lateral side (e.g., the amount 404) in a range from 50 Å to 200 Å, such as in a range from 60 Å to 70 Å. Further, the cleaning process (e.g., the dHF acid) isotropically etches the pad dielectric layer 206 at a smaller, equal, or larger rate than the mask dielectric layer 208, and hence, the pad dielectric layer 206 may have additional lateral reductions 406 from respective sidewalls of the mask dielectric layer 208 (e.g., undercutting the mask dielectric layer 208). As shown in FIG. 4, sidewalls of the pad dielectric layer 206 are under the mask dielectric layer 208 after the cleaning process. In some examples, the pad dielectric layer 206 may be pulled back from a corresponding sidewall of a recess 302, 304 a distance in a range from 50 Å to 200 Å. In some examples, sidewalls of the pad dielectric layer 206 may be aligned to corresponding sidewalls of the mask dielectric layer 208 after the cleaning process.

According to some examples, by implementing a pad dielectric layer 206 and mask dielectric layer 208 having etch rates (e.g., the etch rates resulting in the structural features described with reference to FIG. 4) to the etchant in the cleaning process, the mask dielectric layer 208 may be pulled back by the cleaning process. This may obviate an additional processing step to etch the mask dielectric layer 208, such as by a phosphoric acid, that may damage (e.g., roughen) exposed surfaces of the semiconductor substrate 202 and/or cause contamination in the isolation structure (e.g., phosphorus contamination at the sidewall of the semiconductor substrate 202) that is to be formed. Additionally, obviating such an additional processing step may reduce processing costs and increase throughput. Further, avoiding contamination by such an additional processing step may increase yield.

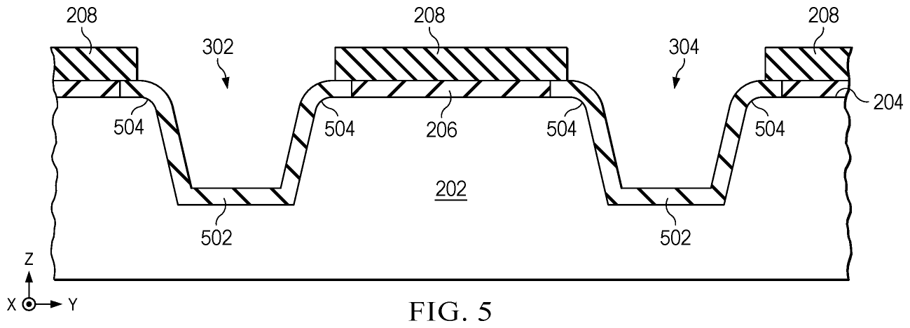

Referring to block 110 of FIG. 1 and to FIG. 5, a first dielectric liner 502 is formed in the recess 302, 304. In some examples, the first dielectric liner 502 is an oxide, such as silicon oxide. In some examples, the first dielectric liner 502 is formed using an oxidation process, such as thermal oxidation, ISSG oxidation, or the like. The oxidation process oxidizes semiconductor material at surfaces of the semiconductor substrate 202 that define the recesses 302, 304 and at the upper surface 204 of the semiconductor substrate 202 where the pad dielectric layer 206 was pulled back. In examples in which the semiconductor material of the semiconductor substrate 202 is silicon, the first dielectric liner 502 may be silicon oxide. The oxidation process may consume the semiconductor material of the semiconductor substrate 202, which may round corners 504 of the semiconductor substrate 202 where the upper surface 204 meets sidewalls of the recesses 302, 304. A thermal process used for forming the first dielectric liner 502, such as a thermal oxidation, ISSG oxidation, etc., may result in shrinking (e.g., additional vertical and/or lateral reductions) of the mask dielectric layer 208. In some examples, the first dielectric liner 502 may have a thickness in a range from 40 Å to 250 Å.

Referring to block 112 of FIG. 1, optionally, the first dielectric liner 502 is removed, and at block 114, if the first dielectric liner 502 was removed, a second dielectric liner is formed in the recess 302, 304. The first dielectric liner 502 may be removed by an etchant, such as diluted hydrofluoric (dHF) acid. Some loss of the mask dielectric layer 208 may occur from using the etchant (e.g., the dHF acid). The second dielectric liner may be formed like the first dielectric liner 502. In some examples, the second dielectric liner may have a thickness in a range from 800 Å to 1,200 Å. Hereinafter, reference to the first dielectric liner 502 may include the second dielectric liner in examples in which the first dielectric liner 502 was removed and the second dielectric liner was formed. Performance of blocks 112, 114 may be used to tune the rounding of the corners 504 of the recesses 302, 304. Blocks 112, 114 may be performed multiple times to achieve a desired rounding for divot control.

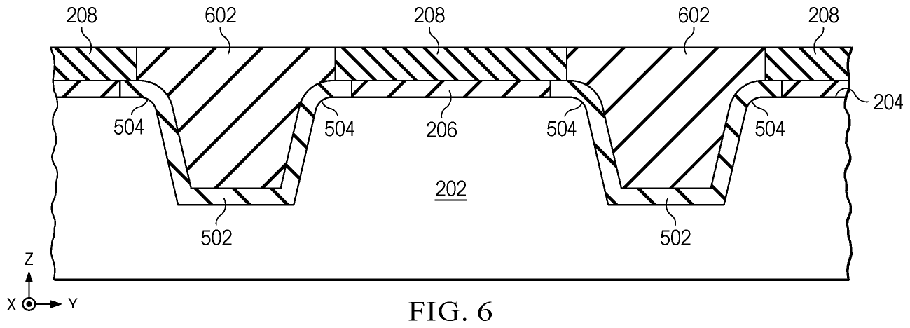

Referring to blocks 116, 118 and to FIG. 6, the recess 302, 304 is filled with a fill dielectric 602, and the fill dielectric 602 is planarized to the mask dielectric layer 208. The fill dielectric 602 may be any appropriate oxide, such as silicon oxide. The fill oxide may be deposited over the first dielectric liner 502 in the recesses 302, 304, such as by high aspect ratio CVD (HAR-CVD), flowable CVD (FCVD), or the like. Any excess fill oxide (e.g., over the mask dielectric layer 208) may be removed by planarizing the fill dielectric 602. The fill dielectric 602 may be planarized using any appropriate planarization process, such as a chemical mechanical polish (CMP).

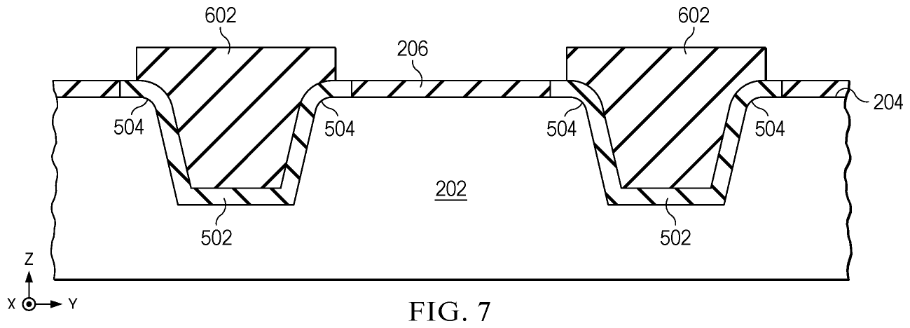

Referring to block 120 of FIG. 1 and to FIG. 7, the mask dielectric layer 208 is removed. The mask dielectric layer 208 may be removed using an etch process (e.g., a wet etch) selective to the mask dielectric layer 208. For example, phosphoric (H₃PO₄) acid may be implemented to remove the mask dielectric layer 208.

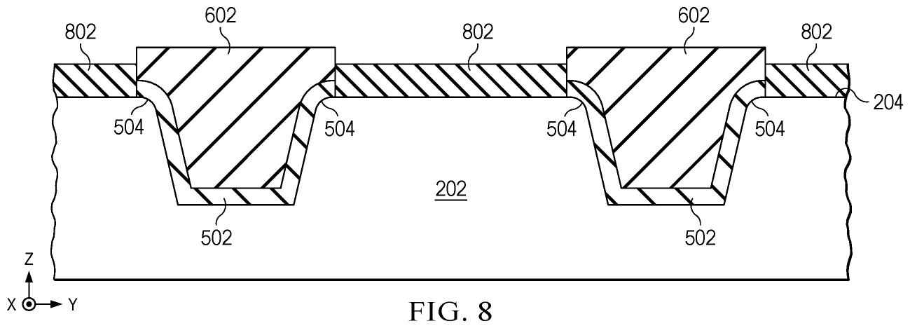

Referring to block 122 of FIG. 1 and to FIG. 8, the pad dielectric layer 206 is removed, and a sacrificial dielectric 802 is formed over the semiconductor substrate 202. In some examples, the sacrificial dielectric 802 is or includes an oxide, such as silicon oxide. The pad dielectric layer 206 may be removed by an appropriate etch process, such as a wet etch (e.g., diluted hydrofluoric (dHF) acid). The sacrificial dielectric 802 may be formed using an oxidation process, such as thermal oxidation, ISSG oxidation, or the like.

Referring to block 124 of FIG. 1, well implantation is performed. One or more wells may be formed by implantation. For example, one or more n-type doped wells may be formed by implantation, and one or more p-type doped wells may be formed by implantation. One or more n-type doped wells may be formed by masking (e.g., by a photoresist using photolithography) areas of the semiconductor substrate 202 where an n-type doped well is not to be formed and implanting n-type dopants into the semiconductor substrate 202. Similarly, one or more p-type doped wells may be formed by masking (e.g., by a photoresist using photolithography) areas of the semiconductor substrate 202 where a p-type doped well is not to be formed and implanting p-type dopants into the semiconductor substrate 202. Any doped well may extend from the upper surface 204 of the semiconductor substrate 202 into a depth in the semiconductor substrate 202, which may be to a level below, at, or above a bottom surface of the recesses 302, 304 and first dielectric liner 502. Although a well is not illustrated in the cross-sectional view of FIG. 8, an n-type doped well 1104 formed by an implantation at block 124 is illustrated in FIG. 11B and subsequent figures.

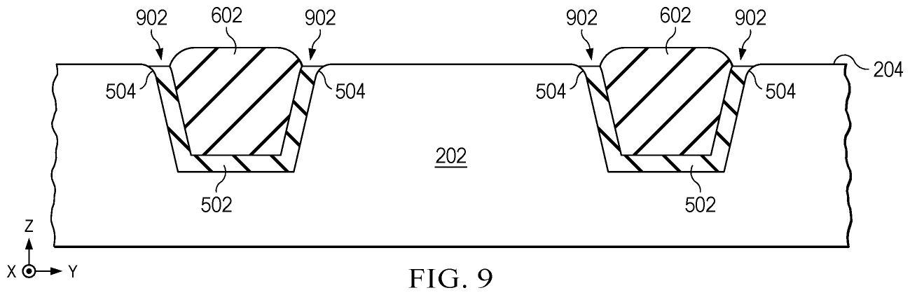

Referring to block 126 of FIG. 1 and to FIG. 9, the fill dielectric 602 and the sacrificial dielectric 802 are etched. Etching the sacrificial dielectric 802 removes the sacrificial dielectric 802 from the upper surface 204 of the semiconductor substrate 202. Etching the fill dielectric 602 reduces a height of the fill dielectric 602 and may round corners of the fill dielectric 602. The etch process may be a wet etch, such as using dHF acid, that isotropically etches the fill dielectric 602 and the sacrificial dielectric 802. The etch process may further etch portions of the first dielectric liner 502 that become exposed during the etch process, such as at the rounded corners 504 of the recesses 302, 304. Etching portions the fill dielectric 602 (and possibly the first dielectric liner 502) below the upper surface 204 of the semiconductor substrate 202 (e.g., at the rounded corners 504 of the recesses 302, 304) may result in divots 902. As illustrated in FIG. 9, divots 902 are formed where rounded corners of the fill dielectric 602 meet the first dielectric liner 502 below the upper surface 204 of the semiconductor substrate 202 and at the rounded corners 504 of the recesses 302, 304.

As shown in FIG. 9, isolation structures are thereby formed in the semiconductor substrate 202. An isolation structure includes the first dielectric liner 502 (or a second dielectric liner) and the fill dielectric 602. Isolation structures may define an active area of the upper surface 204 of the semiconductor substrate 202 in or on which a device may be formed. Any processing on the semiconductor substrate 202 may follow the etching of the fill dielectric 602 and sacrificial dielectric 802 at block 126. FIG. 1 illustrates example processing at blocks 128-138 that may form FETs, such as a p-channel FET (pFET) and/or an n-channel FET (nFET), and p-n junctions for diodes in respective active areas. Various modifications to the subsequent processing of FIG. 1 may be made.

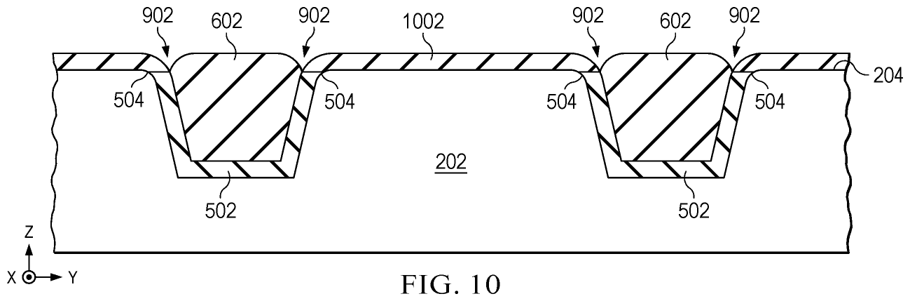

Referring to block 128 of FIG. 1 and to FIG. 10, a gate dielectric layer 1002 is formed on the semiconductor substrate 202. In some examples, the gate dielectric layer 1002 is an oxide. The gate dielectric layer 1002 may be formed by oxidizing the semiconductor material of the semiconductor substrate 202 at the upper surface 204. The oxidation process may be or include a thermal oxidation, ISSG oxidation, or the like. In examples in which the semiconductor material of the semiconductor substrate 202 at the upper surface 204 is silicon, the gate dielectric layer 1002 may be silicon oxide. In other examples, the gate dielectric layer 1002 may be or include other dielectric material and/or may be formed by another process, such as a deposition, like CVD or the like.

Referring to block 130 of FIG. 1 and to FIGS. 11A and 11B, a conductive gate layer 1102 is formed over the gate dielectric layer 1002. The conductive gate layer 1102 is formed over the gate dielectric layer 1002 and the trench isolation structures formed by the first dielectric liner 502 and fill dielectric 602. In some examples, the conductive gate layer 1102 is or includes a semiconductor material, such as polycrystalline silicon (polysilicon), and may be formed by any deposition process, such as CVD. In some examples, the semiconductor material may be doped in situ during deposition and/or may be implanted by a dopant after deposition.

Although not illustrated, a hardmask layer may be formed over the conductive gate layer 1102, e.g., for subsequent patterning of the conductive gate layer 1102. In some examples, the hardmask layer may be or include silicon nitride deposited by CVD, although other hardmask (e.g., dielectric) materials and/or other deposition processes may be used in other examples.

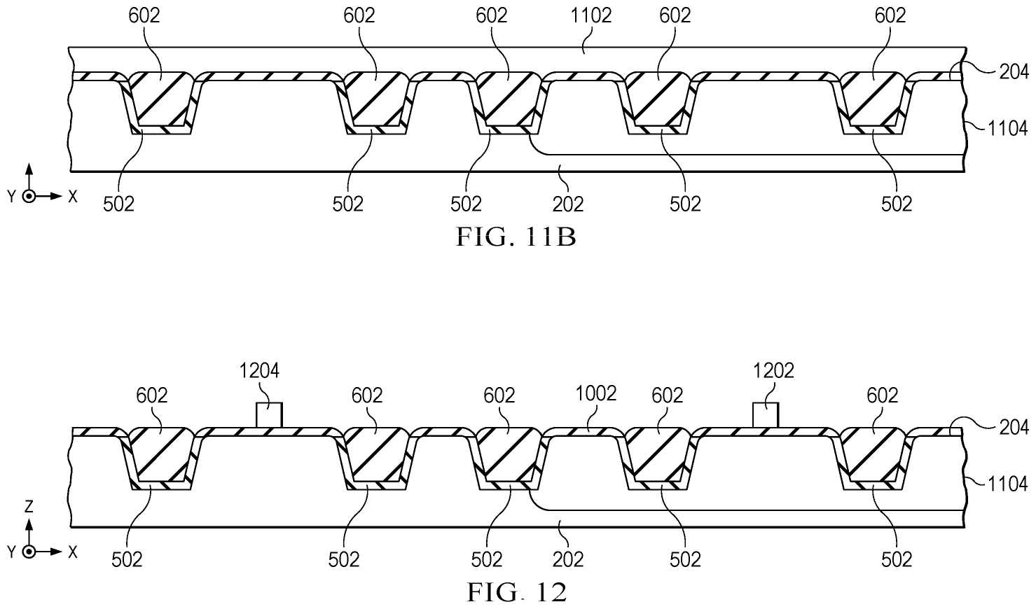

Referring to block 132 of FIG. 1 and to FIG. 12, the conductive gate layer 1102 is patterned. The conductive gate layer 1102 is patterned into gate electrodes 1202, 1204. In some examples, the hardmask layer is patterned corresponding to the pattern of the gate electrodes 1202, 1204, and using the patterned hardmask layer as a mask, the conductive gate layer 1102 is patterned. The hardmask layer may be patterned using appropriate photolithography and etching processes, and the conductive gate layer 1102 may be patterned using an appropriate etching process. For example, an anisotropic etch, such as an RIE, may be implemented.

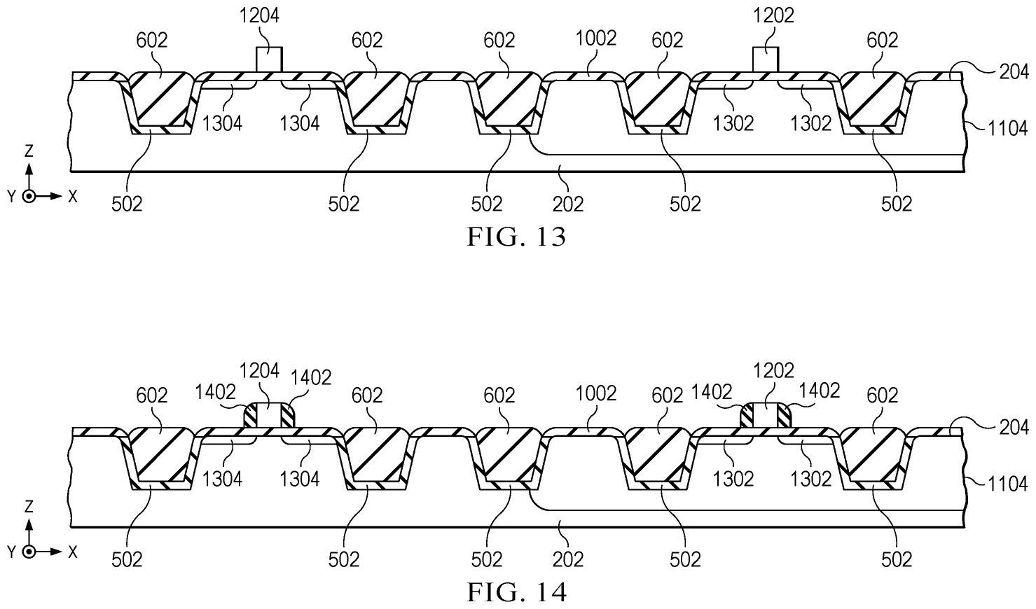

Referring to block 134 of FIG. 1 and to FIG. 13, lightly doped drain regions (LDDs) are formed in the semiconductor substrate 202. As shown in FIG. 13, p-type LDDs 1302 and n-type LDDs 1304 are formed in the semiconductor substrate 202. The p-type LDDs 1302 are in the semiconductor substrate 202 on laterally opposing sides of a gate electrode 1202, and the n-type LDDs 1304 are in the semiconductor substrate 202 on laterally opposing sides of the gate electrode 1204. The p-type LDDs 1302 may be formed by masking (e.g., by a photoresist using photolithography) regions where p-type LDDs are not to be formed and implanting a p-type dopant into the semiconductor substrate 202. The n-type LDDs 1304 may be formed by masking (e.g., by a photoresist using photolithography) regions where n-type LDDs are not to be formed and implanting an n-type dopant into the semiconductor substrate 202.

Referring to block 136 of FIG. 1 and to FIG. 14, gate spacers 1402 are formed along sidewalls of the gate electrodes 1202, 1204. The gate spacers 1402 may be formed by depositing a layer of the material of the gate spacers 1402 conformally over the semiconductor substrate 202 and anisotropically etching the layer such that the gate spacers 1402 remain. The material of the gate spacers 1402 may be any appropriate dielectric material, such as silicon nitride, silicon oxynitride, silicon carbon nitride, the like, or a combination thereof. The layer may be deposited by CVD, PECVD, atomic layer deposition (ALD), or the like. If a hardmask layer was used for patterning the conductive gate layer 1102, any remaining portion of the hardmask layer may be removed from the gate electrodes 1202, 1204 when the layer forming the gate spacers 1402 is etched.

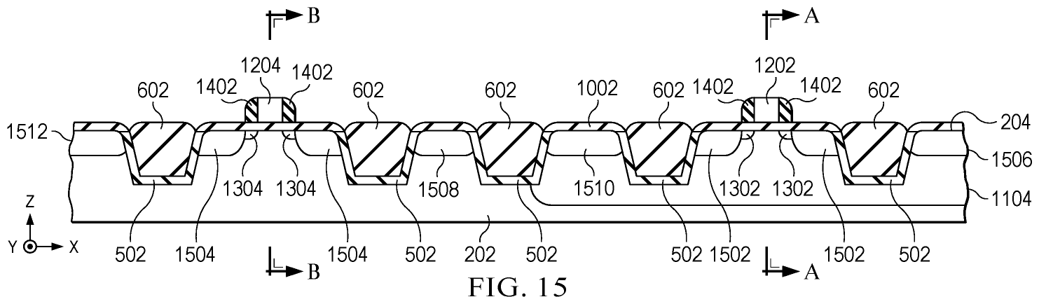

Referring to block 138 of FIG. 1 and to FIG. 15, source/drain regions are formed in the semiconductor substrate 202. P-type source/drain (PSD) regions 1502 and n-type source/drain (NSD) regions 1504 are formed in the semiconductor substrate 202, as shown in FIG. 15. The PSD regions 1502 are on opposing lateral sides of the gate electrode 1202 with the p-type LDDs 1302 therebetween. The NSD regions 1504 are on opposing lateral sides of the gate electrode 1204 with the n-type LDDs 1304 therebetween. Additionally, as shown in FIG. 15, an n-type substrate contact region 1506, a p-type substrate contact region 1508, an anode region 1510, and a cathode region 1512 may be formed in the semiconductor substrate 202. An implantation is performed to form the PSD regions 1502, p-type substrate contact region 1508, and anode region 1510. The PSD regions 1502, p-type substrate contact region 1508, and anode region 1510 may be formed by masking (e.g., by a photoresist using photolithography) areas where p-type regions are not to be formed by the implantation and implanting a p-type dopant into the semiconductor substrate 202. An implantation is performed to form the NSD regions 1504, n-type substrate contact region 1506, and cathode region 1512. The NSD regions 1504, n-type substrate contact region 1506, and cathode region 1512 may be formed by masking (e.g., by a photoresist using photolithography) areas where n-type regions are not to be formed by the implantation and implanting an n-type dopant into the semiconductor substrate 202.

In FIG. 15, a pFET, an nFET, and p-n junctions of diodes are shown formed on the semiconductor substrate 202. The pFET includes, among other things, the gate electrode 1202 and the PSD regions 1502. The nFET includes, among other things, the gate electrode 1204 and the NSD regions 1504. A p-n junction of a diode is formed between the anode region 1510 and the n-type doped well 1104. A p-n junction of another diode is formed between the cathode region 1512 and the p-type doped semiconductor substrate 202.

FIG. 15 further shows cross-sections A-A, B-B through the pFET and nFET, respectively. The cross-sections A-A, B-B may be as shown in FIG. 11A where the respective gate electrode 1202, 1204 is the conductive gate layer 1102 and except that the n-type doped well 1104 is not illustrated for the cross-section A-A of the pFET. As shown in FIG. 11A, the gate electrodes 1202, 1204 wrap around the rounded corners 504 of the semiconductor substrate 202 at respective isolation structures (e.g., at divots 902). Such wrapping may be engineered to have a target active area utilization while reducing a subthreshold parasitic transistor effect. Some amount of divot 902 may help prevent source-to-drain shorting in the active area of the respective FET. Having too deep of a divot 902 may create a parasitic transistor in the respective FET, which has a lower threshold voltage than the respective FET. The lower threshold voltage may permit the parasitic transistor to turn on before the respective FET, which may result in an undesirable current-voltage curve and may degrade sub-threshold voltage mismatch. Some examples described above may permit the divot 902 to be engineered to a target utilization of the active area of the semiconductor substrate while avoiding or reducing parasitic effects.

Although various examples have been described in detail, it should be understood that various changes, substitutions, and alterations can be made therein without departing from the scope defined by the appended claims.

What is claimed is:

1. A method, comprising:
forming a first dielectric layer over a semiconductor substrate;
forming a second dielectric layer over the first dielectric layer;
forming a recess through the second dielectric layer and the first dielectric layer into the semiconductor substrate;
cleaning the recess including using an etchant, a ratio of an etch rate of the first dielectric layer by the etchant to an etch rate of the second dielectric layer by the etchant being in a range from 0.10 to 4; and
filling the recess in the semiconductor substrate with a dielectric material.

2. The method of claim 1, wherein:
the first dielectric layer is silicon oxide; and
the second dielectric layer is silicon nitride.

3. The method of claim 2, wherein the etchant includes hydrofluoric acid.

4. The method of claim 1, wherein the etchant laterally pulls back the second dielectric layer and the first dielectric layer, a sidewall of the first dielectric layer being under the second dielectric layer or aligned to a sidewall of the second dielectric layer after cleaning the recess.

5. The method of claim 4, further comprising:
forming an oxide layer after cleaning the recess and before filling the recess, wherein the second dielectric layer shrinks as a result of forming the oxide layer.

6. The method of claim 1, wherein forming the second dielectric layer includes depositing the second dielectric layer in a deposition process, the deposition process including flowing hexachlorodisilane gas and ammonia gas.

7. The method of claim 6, wherein forming the second dielectric layer includes annealing the second dielectric layer after depositing the second dielectric layer.

8. The method of claim 1, wherein forming the second dielectric layer includes depositing the second dielectric layer in a deposition process, the deposition process including flowing silane gas and ammonia gas with a process temperature less than 375° C.

9. The method of claim 8, wherein forming the second dielectric layer includes annealing the second dielectric layer after depositing the second dielectric layer.

10. The method of claim 1, wherein forming the second dielectric layer includes depositing the second dielectric layer in a deposition process, the deposition process including:
in a first sub-process, flowing silane gas with a first silane flow rate and flowing ammonia gas with a first ammonia flow rate; and
in a second sub-process after the first sub-process, flowing silane gas with a second silane flow rate and flowing ammonia gas with a second ammonia flow rate, the second silane flow rate being greater than the first silane flow rate, the second ammonia flow rate being greater than the first ammonia flow rate.

11. The method of claim 10, wherein the deposition process further includes:
in a third sub-process after the first sub-process and before the second sub-process, flowing nitrogen gas and helium gas in an absence of silane gas and ammonia gas; and
in a fourth sub-process after the second sub-process, flowing nitrogen gas and helium gas in an absence of silane gas and ammonia gas.

12. The method of claim 11, wherein the deposition process further includes: in a fifth sub-process before the first sub-process, flowing nitrogen gas and helium gas in an absence of silane gas and ammonia gas.

13. The method of claim 12, wherein the first sub-process, the second sub-process, the third sub-process, the fourth sub-process, and the fifth sub-process are performed in a process chamber while maintaining a pressure of the process chamber at a sub-atmospheric level.

14. The method of claim 10, wherein the deposition process further includes:
in a third sub-process after the first sub-process and before the second sub-process, performing a densification; and
in a fourth sub-process after the second sub-process, performing a densification.

15. The method of claim 10, wherein:
the first sub-process includes flowing a helium gas; and
the second sub-process includes flowing a helium gas.

16. A method, comprising:
forming an oxide layer over a semiconductor substrate;
forming a nitride layer over the oxide layer, the nitride layer having an etch rate by hydrofluoric acid in a range from 20 Angstroms per minute (Å/m) to 30 Å/m;
forming a trench through the nitride layer and the oxide layer into the semiconductor substrate;
cleaning the trench including using hydrofluoric acid; and
filling the trench in the semiconductor substrate with a dielectric material.

17. The method of claim 16, wherein cleaning the trench including using hydrofluoric acid pulls back a sidewall of the nitride layer from a boundary of the trench a distance in a range from 50 Å to 200 Å.

18. The method of claim 16, wherein forming the nitride layer includes depositing the nitride layer in a deposition process, wherein the deposition process includes:
a flow rate of hexachlorodisilane gas in a range from 5 standard cubic centimeter (sccm) to 100 sccm;
a flow rate of ammonia gas in a range from 100 sccm to 3,000 sccm;
a process temperature in a range from 450° C. to 650° C.; and
a chamber pressure in a range from 0.1 torr to 0.5 torr.

19. The method of claim 16, wherein forming the nitride layer includes depositing the nitride layer in a deposition process, wherein the deposition process includes:
a flow rate of silane gas in a range from 200 standard cubic centimeter (sccm) to 350 sccm;
a flow rate of ammonia gas in a range from 700 sccm to 1,000 sccm;
a process temperature less than 375° C.;
a chamber pressure in a range from 4 torr to 8 torr; and
a radio frequency (RF) power in a range from 150 Watts (W) to 300 W.

20. The method of claim 16, wherein forming the nitride layer includes depositing the nitride layer in a deposition process performed in a process chamber while maintaining a pressure of the process chamber at a subatmospheric level, wherein the deposition process includes:
in a first sub-process:
a flow rate of nitrogen gas in a range from 8,000 standard cubic centimeter (sccm) to 12,000 sccm; and
a flow rate of helium gas in a range from 8,000 sccm to 12,000 sccm;
in a second sub-process after the first sub-process:
a flow rate of silane gas in a range from 15 sccm to 35 sccm;
a flow rate of ammonia gas in a range from 150 sccm to 400 sccm;
a process temperature in a range from 400° C. to 575° C.;
a chamber pressure in a range from 6 torr to 10 torr; and
a radio frequency (RF) power in a range from 200 Watts (W) to 400 W;
in a third sub-process after the second sub-process:
a flow rate of nitrogen gas in a range from 12,000 sccm to 16,000 sccm; and
a flow rate of helium gas in a range from 8,000 sccm to 12,000 sccm;
in a fourth sub-process after the third sub-process:
a flow rate of silane gas in a range from 160 sccm to 300 sccm;
a flow rate of ammonia gas in a range from 500 sccm to 800 sccm;
a process temperature in a range from 400° C. to 575° C.;
a chamber pressure in a range from 2 torr to 4 torr; and
a RF power in a range from 75 Watts (W) to 150 W; and
in a fifth sub-process after the fourth sub-process:
a flow rate of nitrogen gas in a range from 12,000 sccm to 16,000 sccm; and
a flow rate of helium gas in a range from 8,000 sccm to 12,000 sccm.
